(19) United States
(12) Patent Application Publication
(10) Pub. No.: US 2026/0130007 A1
(43) Pub. Date: May 7, 2026

(54) SUPER-LUMINESCENT DIODE AND EXTERNAL CAVITY LASER INCLUDING THE SAME

(71) Applicant: ELECTRONICS AND TELECOMMUNICATIONS RESEARCH INSTITUTE, Daejeon (KR)

(72) Inventors: Su Hwan OH, Daejeon (KR); Kisoo KIM, Daejeon (KR); Hongseung KIM, Daejeon (KR)

(21) Appl. No.: 19/319,269

(22) Filed: Sep. 4, 2025

(30) Foreign Application Priority Data
Nov. 7, 2024 (KR) 10-2024-0156660

(51) Int. Cl. H10H 20/00; H01S 5/10; H01S 5/14; H01S 5/20; H01S 5/22; H01S 5/343

(52) U.S. Cl. CPC H10H 20/042; H01S 5/101; H01S 5/1014; H01S 5/14; H01S 5/2031; H01S 5/2207; H01S 5/343

(57) ABSTRACT

Disclosed are a super-luminescent diode and an external cavity laser including the same. The diode includes a substrate including a gain region, a window region spaced apart from the gain region, and a tapered region between the window region and the gain region, an active waveguide layer including a lower waveguide layer provided on the substrate and extending from the gain region to the window region, and an upper waveguide layer provided on the lower waveguide layer and extending from the gain region to the tapered region, and a clad layer provided on the lower waveguide layer and the upper waveguide layer of the active waveguide layer. The lower waveguide layer and the upper waveguide layer may include asymmetric separate confinement heterostructure (SCH) layers.

### CROSS-REFERENCE TO RELATED APPLICATION

This U.S. non-provisional patent application claims priority under 35 U.S.C. § 119 of Korean Patent Application No. 10-2024-0156660, filed on Nov. 7, 2024, the entire contents of which are hereby incorporated by reference.

### BACKGROUND

The present disclosure herein relates to a super-luminescent diode, and more particularly, to a super-luminescent diode operating at high power and high efficiency and an external cavity laser including the same.

Typically, a super-luminescent diode (SLD) is a light source having an intermediate feature of a light-emitting diode (LED) and a laser diode (LD), and has recently emerged as a light source of an optical sensor. Such an SLD is applied as a light source of a fiber-optic gyroscope used as a navigation device in a vehicle, a ship, an aircraft, etc., optical coherence tomography that is a diagnostic imaging technique for examining, with high resolution, multiple faces of micro-structure in a living tissue, and an external cavity laser (ECL).

### SUMMARY

The present disclosure provides a super-luminescent diode capable of operating at high power and high efficiency, and an external cavity laser including the same.

An embodiment of the inventive concept provides a super-luminescent diode comprising: a substrate including a gain region, a window region spaced apart from the gain region, and a tapered region between the window region and the gain region; an active waveguide layer including a lower waveguide layer provided on the substrate and extending from the gain region to the window region, and an upper waveguide layer provided on the lower waveguide layer and extending from the gain region to the tapered region; and a clad layer provided on the lower waveguide layer and the upper waveguide layer of the active waveguide layer. Here, each of the lower waveguide layer and the upper waveguide layer may include asymmetric separate confinement heterostructure (SCH) layers.

In an embodiment, the lower waveguide layer and the upper waveguide layer may be tapered in opposite directions in the tapered region.

In an embodiment, the lower waveguide layer may comprise: a first lower SCH layer having an energy bandgap higher than that of the substrate; a second lower SCH layer provided on the first lower SCH layer, being thinner than the first lower SCH layer, and having an energy bandgap higher than that of the first lower SCH layer; and a third lower SCH layer provided on the second lower SCH layer and having an energy bandgap higher than that of the second lower SCH layer.

In an embodiment, the upper waveguide layer may comprise: a fourth lower SCH layer provided on the third lower SCH layer and having an energy bandgap higher than that of the third lower SCH layer; and a core layer provided on the fourth lower SCH layer and including quantum well structures and barrier layers between the quantum well structures.

In an embodiment, the upper waveguide layer may be provided on the core layer and further include a first upper SCH layer having same energy bandgap as that of the fourth lower SCH layer.

In an embodiment, the upper waveguide layer may be provided on the first upper SCH layer and further include a second upper SCH layer having same energy bandgap as that of the third lower SCH layer.

In an embodiment, the upper waveguide layer may be provided on the second upper SCH layer and further include a third upper SCH layer having same energy bandgap as that of the second lower SCH layer.

In an embodiment, the upper waveguide layer may be provided on the third upper SCH layer and further include a fourth upper SCH layer having same energy bandgap as that of the first lower SCH layer.

In an embodiment, each of the first lower SCH layer, the second lower SCH layer, the third lower SCH layer, the fourth lower SCH layer, the core layer, the first upper SCH layer, the second upper SCH layer, the third upper SCH layer, and the fourth upper SCH layer may InGaAsP.

In an embodiment, the super-luminescent diode may further include: an ohmic contact layer on the clad layer; an upper electrode on the ohmic contact layer; and a lower electrode under the substrate.

In an embodiment of the inventive concept, an external cavity laser comprises: an element substrate; a super-luminescent diode provided at one side of the element substrate; a mirror provided at another side of the element substrate; and an optical filter provided between the mirror and the super-luminescent diode. Here, the super-luminescent diode may comprise: a substrate including a gain region, a window region spaced apart from the gain region, and a tapered region between the window region and the gain region; an active waveguide layer including a lower waveguide layer provided on the substrate and extending from the gain region to the window region, and an upper waveguide layer provided on the lower waveguide layer and extending from the gain region to the tapered region; and a clad layer provided on the lower waveguide layer and the upper waveguide layer of the active waveguide layer. Each of the lower waveguide layer and the upper waveguide layer may include asymmetric separate confinement heterostructure (SCH) layers.

In an embodiment, the external cavity laser may further comprise a first coating layer provided at one side of the super-luminescent diode; and a second coating layer provided at another side of the super-luminescent diode.

In an embodiment, the first coating layer may comprise a half-transmissive coating layer or a total-reflective coating layer, and the second coating layer may comprise an anti-reflective layer.

In an embodiment, the filter may comprise: a filter substrate; half-transmissive layers on the filter substrate; and transmissive layers between the half-transmissive layers.

In an embodiment, the external cavity laser may further comprise a lens provided between the filter and the super-luminescent diode.

In an embodiment of the inventive concept, a super-luminescent diode manufacturing method comprises: providing a lower waveguide layer and an upper waveguide layer on a substrate including a gain region, a window region spaced apart from the gain region, and a tapered region between the gain region and the window region; removing a portion of the upper waveguide layer in the tapered region and the window region to taper the upper waveguide layer in the tapered region in one direction; and removing a portion of the upper waveguide layer in the gain region and a portion of the lower waveguide layer and the upper waveguide layer in the gain region, the tapered region, and the window region to taper the lower waveguide layer in a direction opposite to the tapering direction of the upper waveguide layer. Here, each of the upper waveguide layer and the lower waveguide layer may include asymmetric SCH layers.

In an embodiment, the super-luminescent diode manufacturing method may further comprise providing a current blocking layer on walls of the lower waveguide layer and the upper waveguide layer.

In an embodiment, the super-luminescent diode manufacturing method may further comprise: providing a clad layer on the current blocking layer, the upper waveguide layer, and the lower waveguide layer; providing an ohmic contact layer on the clad layer; providing an upper electrode on the ohmic contact layer; and providing a lower electrode on a lower surface of the substrate.

In an embodiment, the lower waveguide layer may comprise: a first lower SCH layer having an energy bandgap higher than that of the substrate; a second lower SCH layer provided on the first lower SCH layer, being thinner than the first lower SCH layer, and having an energy bandgap higher than that of the first lower SCH layer; and a third lower SCH layer provided on the second lower SCH layer and having an energy bandgap higher than that of the second lower SCH layer.

In an embodiment, the upper waveguide layer may comprise: a fourth lower SCH layer provided on the third lower SCH layer and having an energy bandgap higher than that of the third lower SCH layer; a core layer provided on the fourth lower SCH layer and including quantum well structures and barrier layers between the quantum well structures; a first upper waveguide layer provided on the core layer and having same energy bandgap as that of the fourth lower SCH layer; a second upper SCH layer provided on the first upper SCH layer and having same energy bandgap as that of the third lower SCH layer; a third lower SCH layer provided on the second upper SCH layer and having same energy bandgap as that of the second lower SCH layer; and a fourth upper SCH layer provided on the third upper SCH layer and having same energy bandgap as that of the first lower SCH layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view showing an example super-luminescent diode according to the present inventive concept;

FIGS. 2A to 2D are cross-sectional views taken along lines I-I′, II-II′, III-III′, and IV-IV′ of FIG. 1, respectively;

FIG. 2E is a graph showing energy bandgaps of a substrate, an active waveguide layer, and a clad layer of FIG. 2D;

FIG. 3 is a process cross-sectional view showing a lower waveguide layer, an upper waveguide layer, and a clad layer of FIGS. 1 and 2A;

FIG. 4A is a plan view showing an example first hard mask film provided on the clad layer of FIG. 3;

FIG. 4B is a process cross-sectional view taken along line V-V′ of FIG. 4A;

FIG. 5A is a plan view showing an example second hard mask film provided on the clad layer of FIG. 4B;

FIGS. 5B, 5C, and 5D are process cross-sectional views of a gain region, a tapered region, and a window region of FIG. 5A;

FIGS. 6A to 6C are process cross-sectional views showing an example current blocking layer, clad layer, and ohmic contact layer of FIGS. 5B to 5D;

FIG. 7 is a cross-sectional view showing an external cavity laser according to an application example of the inventive concept; and

FIG. 8 is a cross-sectional view showing an external cavity laser according to an application example of the inventive concept.

### DETAILED DESCRIPTION

Hereinafter, example embodiments of the present disclosure will be described in conjunction with the accompanying drawings. The above and other aspects, features, and advantages of the present disclosure will become apparent from the detailed description of the following embodiments in conjunction with the accompanying drawings. However, it should be understood that the present invention is not limited to the following embodiments and may be embodied in different ways. Rather, the embodiments are provided so that so that this disclosure will be thorough and complete and will fully convey the concept of the invention to those skilled in the art, and the present disclosure will only be defined by the appended claims. Throughout this specification, like numerals refer to like elements.

The terminology used herein is for the purpose of describing embodiments and is not intended to limit the scope of the present disclosure. As used herein, the singular forms “a”, “an” and “the” are intended to include the plural forms as well, unless the context clearly indicates otherwise. It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof. Also, as just example embodiments, reference numerals shown according to an order of description are not limited to the order.

Moreover, example embodiments will be described herein with reference to cross-sectional views and/or plane views that are idealized example illustrations. In the drawings, the thickness of layers and regions are exaggerated for effective description of the technical details. Accordingly, variations from the shapes of the illustrations as a result, for example, of manufacturing techniques and/or tolerances, are to be expected. Thus, example embodiments should not be construed as limited to specific shapes illustrated herein but are to include deviations in shapes that result from manufacturing.

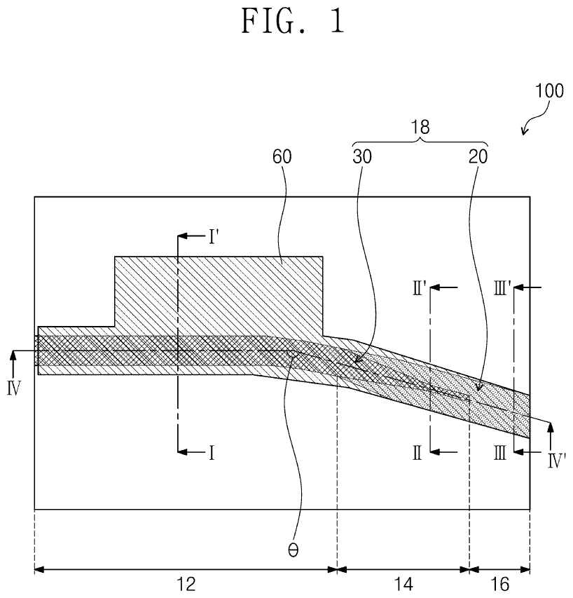

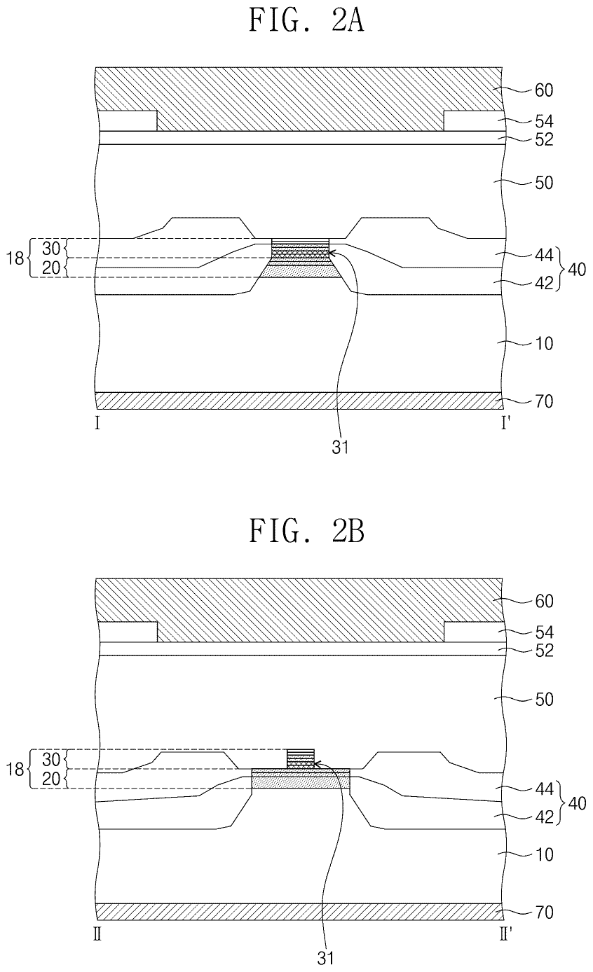

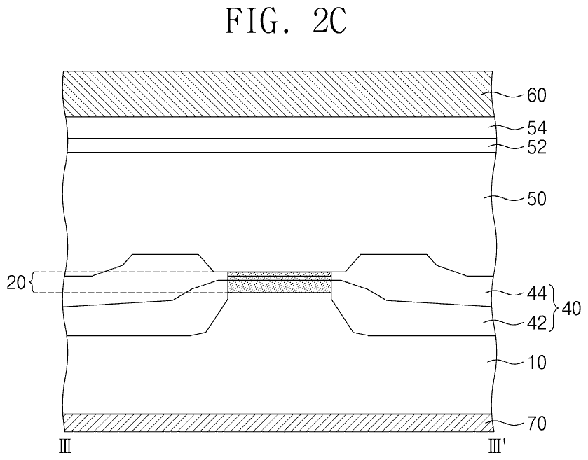

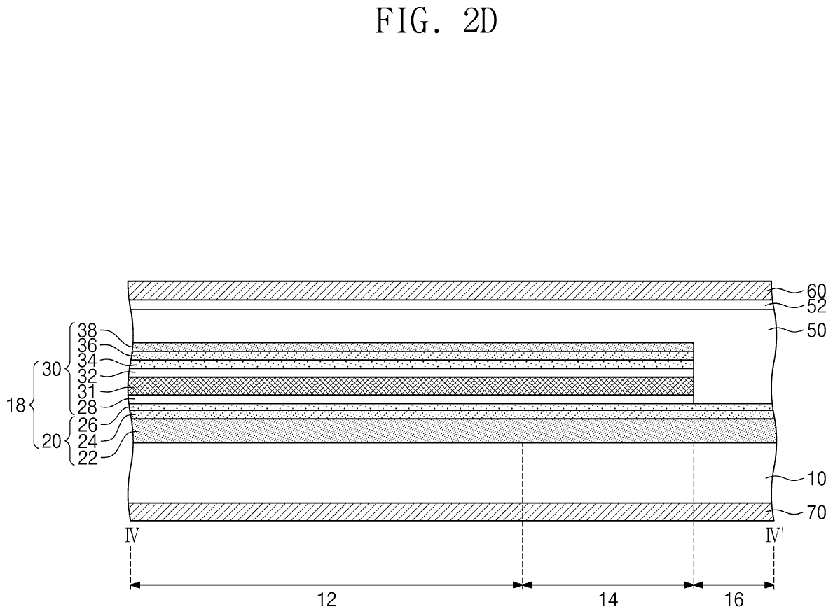

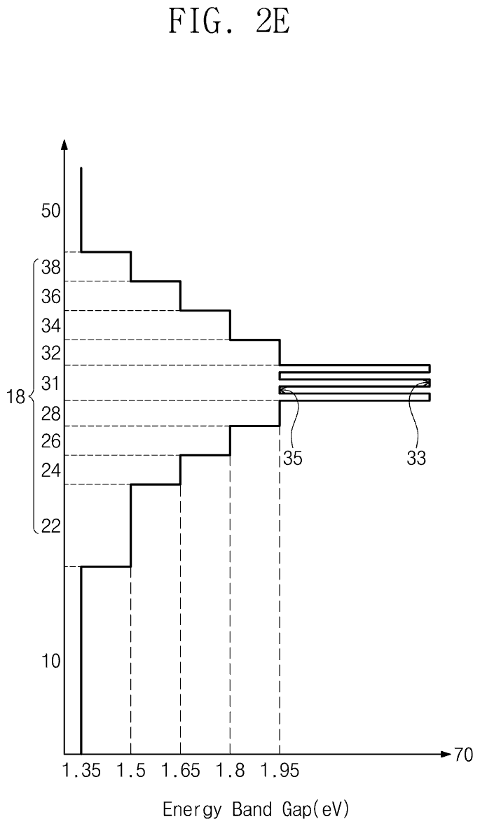

FIG. 1 shows an example super-luminescent diode 100 according to the present inventive concept. FIGS. 2A to 2D are cross-sectional views taken along lines I-I′, II-II′, III-III′, and IV-IV′ of FIG. 1, respectively. FIG. 2E shows energy bandgaps of a substrate 10, an active waveguide layer 18, and a clad layer 50 of FIG. 2D.

Referring to FIGS. 1 and 2A to 2D, the super-luminescent diode 100 of the inventive concept may include the substrate 1, the active waveguide layer 18, a current blocking layer 40, the clad layer 50, an upper electrode 60, and a lower electrode 70.

The substrate 10 may have a gain region 12, a tapered region 14, and a window region 16. The gain region may be provided at one side of the substrate 10. The window region 16 may be spaced apart from the gain region 12 to be provided at the other side of the substrate 10. The tapered region 14 may be provided between the gain region 12 and the window region 16. The substrate 10 may include n-type InP.

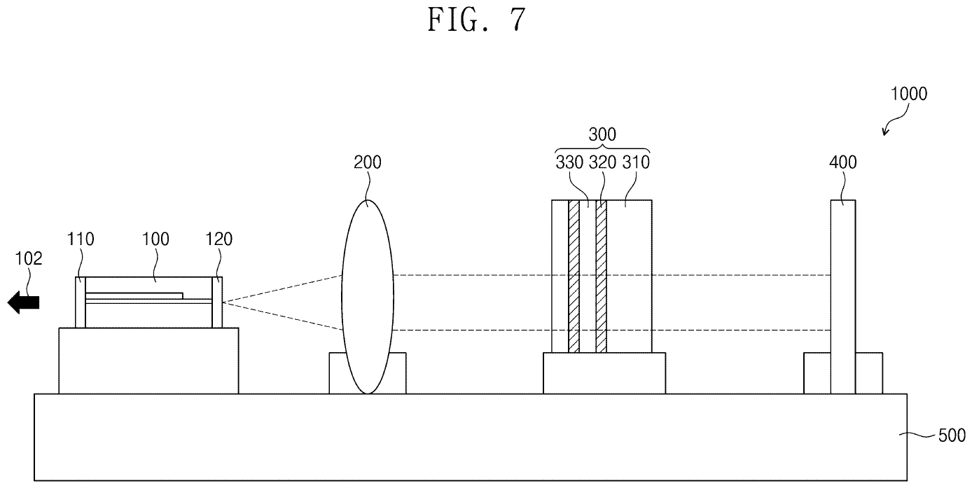

The active waveguide layer 18 may be provided on the substrate 10. The active waveguide layer 18 may extend from the gain region 12 to the window region 16. The active waveguide layer 18 may have a linewidth of about 1 μm to about 2 μm in the gain region 12, and a linewidth of about 0 to about 70 μm in the window region 16. The active waveguide layer 18 may be curved or bent at an angle θ of about 5° to about 15° in the tapered region 14. The bent active waveguide layer 18 may increase the characteristics of a far field pattern. The active waveguide layer 18 may have the thickness of about 0.2 to about 1 μm. The active waveguide layer 18 may include asymmetric separate confinement heterostructure (SCH) layers. For example, the active waveguide layer 18 may include a plurality of asymmetric 4-step SCH layers. In addition, the active waveguide layer 18 may have a planar buried heterostructure (PBH). The active waveguide layer 18 may acquire the gain of laser light 102 (of FIG. 7) to generate the laser light 102. According to an example, the active waveguide layer 19 may include a lower waveguide layer 20 and an upper waveguide layer 30.

The lower waveguide layer 20 may be provided on the substrate 10. The lower waveguide layer 20 may be longer than the upper waveguide layer 30. The lower waveguide layer 20 may extend from the gain region 12 to the window region 16. The lower waveguide layer 20 may be wider in the gain region 12 than in the window region 16. In the tapered region 14, the lower waveguide layer 14 may be curved or bent at an angle θ of about 5° to about 15° in the tapered region 14. The lower waveguide layer 20 may include an asymmetric SCH InGaAsP. For example, the lower waveguide layer 20 may include asymmetric 3-step SCH InGaAsP layers. Alternatively, the lower waveguide layer 20 may include asymmetric 4-step SCH InGaAsP layers, and the inventive concept is not limited thereto. According to an example, the lower waveguide layer 20 may include a first lower SCH layer 22, a second lower SCH layer 24, and a third lower SCH layer 26.

The first lower SCH layer 22 may be provided between the substrate 10 and the second lower SCH layer 24. The first lower SCH layer 22 may be thicker than the second lower SCH layer 24. The first lower SCH layer 22 may have an energy bandgap higher than that of the substrate 10 and a lower energy bandgap than the second lower SCH layer 24. The energy bandgap of the substrate 10 may be about 1.35 eV, and the energy bandgap of the first lower SCH layer 22 may be about 1.5 eV. The energy bandgap of the second lower SCH layer 24 may be about 1.65 eV. The lower surface or bottom surface of the first lower SCH layer 22 may have a linewidth of about 3 to about 6 μm.

The second lower SCH layer 24 may be provided between the first lower SCH layer 22 and the third lower SCH layer 26. The second lower SCH layer 24 may have an energy bandgap higher than that of the first lower SCH layer 22.

The third lower SCH layer 26 may be provided between the second SCH layer 24 and the upper waveguide layer 30. The third lower SCH layer 26 may have an energy bandgap higher than that of the second lower SCH layer 24. The energy bandgap of the third lower SCH layer 26 may be about 1.8 eV.

The upper waveguide layer 30 may be provided on the third lower SCH layer 26. The upper waveguide layer 30 may acquire the gain of the laser light 102. The upper waveguide layer 30 may be curved or bent at an angle θ of about 5° to about 15° in the tapered region 14. The upper waveguide layer 30 in the gain region 12 may be aligned with the lower waveguide layer 20. The upper waveguide layer 30 in the tapered region 14 and the window region 16 may be narrower than the lower waveguide layer 20 in a plan view. In the tapered region 14, one terminal or tail of the upper waveguide layer 30 may have a linewidth of about 1 μm to about 2 μm. Unlike this, one terminal or tail of the upper waveguide layer 30 may have a linewidth of about 0.5 μm or narrower.

In particular, the lower waveguide layer 20 and the upper waveguide layer 30 may be tapered in opposite directions in the tapered region 14. The lower waveguide layer 20 may be tapered in one direction, and the upper waveguide layer 30 may be tapered in the direction opposite to the tapered direction of the lower waveguide layer 20. The lower waveguide layer 20 and the upper waveguide layer 30 may have a double-tapered (e.g., 2-step spot size converter (SSC) structure to increase optical coupling efficiency.

Accordingly, the super-luminescent diode 100 according to the inventive concept may use the lower waveguide layer 20 and the upper waveguide layer 30, which are tapered in the opposite directions, to operate at high power and high efficiency.

For example, the upper waveguide layer 30 may include InGaAsP. Furthermore, the upper waveguide layer 30 may include an asymmetric 1-step SCH InGaAsP layer and an asymmetric 4-step SCH InGaAsP layer. According to an example, the upper waveguide layer 30 may include a fourth lower SCH layer 28, a core layer 31, a first upper SCH layer 36, a second upper SCH layer 34, a third upper SCH layer 36, and a fourth SCH layer 38.

The fourth lower SCH layer 28 may be provided on the third lower SCH layer 26. The fourth lower SCH layer 28 may have an energy bandgap higher than that of the third lower SCH layer 26. The energy bandgap of the fourth lower SCH layer 28 may be about 2 eV.

The core layer 31 may be provided on the fourth lower SCH layer 28. The core layer 31 may acquire the gain of the laser light 102. For example, the core layer 31 may have the thickness of about 0.1 μm to about 0.2 μm. The core layer 31 may have multi-quantum well layers 33 and barrier layers 35. The multi-quantum well layers 33 may have an energy bandgap higher than that of the fourth lower SCH layer 28. The energy bandgap of the multi-quantum well layers 33 may be about 1.95 eV to about 4 eV. For example, the multi-quantum well layers 33 may include Well InGaAsP. Alternatively, the multi-quantum well layers 33 may include InGaAs/InGaAsP, and the inventive concept is not limited thereto. The barrier layers 35 may be provided between the multi-quantum well layers 33. The multi-quantum well layers 33 and the barrier layers 35 may be alternately laminated. The barrier layers 35 may have the same or similar energy bandgap as the fourth lower SCH layer 28. The barrier layers 35 may include barrier InGaAsP. The energy bandgap of the barrier layers 35 may be about 1.95 eV to about 2 eV.

The first upper SCH layer 32 may be provided on the core layer 31. The first upper SCH layer 32 may have a lower energy bandgap than the multi-quantum well layers 33 of the core layer 31. The first upper SCH layer 32 may have the same or similar energy bandgap as the fourth lower SCH layer 28. The energy bandgap of the first upper SCH layer 32 may be about 1.95 eV to about 2 eV.

The second upper SCH layer 34 may be provided on the first upper SCH layer 32. The second upper SCH layer 34 may have n lower energy bandgap than the first upper SCH layer 32. The second upper SCH layer 34 may have the same or similar energy bandgap as the third lower SCH layer 26. The energy bandgap of the second upper SCH layer 34 may be about 1.8 eV.

The third upper SCH layer 36 may be provided on the second upper SCH layer 34. The third upper SCH layer 36 may have a lower energy bandgap than the second upper SCH layer 34. The third upper SCH layer 36 may have the same or similar energy bandgap as the second lower SCH layer 24. The energy bandgap of the third upper SCH layer 36 may be about 1.65 eV.

The fourth upper SCH layer 38 may be provided on the third upper SCH layer 36. The fourth upper SCH layer 38 may have a lower energy bandgap than the third upper SCH layer 36. The fourth upper SCH layer 38 may have the same or similar energy bandgap as the first lower SCH layer 22. The energy bandgap of the fourth upper SCH layer 38 may be about 1.5 eV.

The first upper SCH layer 32, the second upper SCH layer 34, the third upper SCH layer 36, and the four upper SCH layer 38 may be thinner than the first lower SCH layer 22, the second lower SCH layer 24, the third lower SCH layer 26, and the fourth lower SCH layer 28. For example, the first lower SCH layer 22 may have a thickness of about 0.1 μm to about 0.35 μm, the second lower SCH layer 24, the third lower SCH layer 26, and the four lower SCH layer 28, and the first higher SCH layer 32, the second higher SCH layer 34, the third higher SCH layer 36, and the fourth higher SCH layer 38.

The current blocking layers 40 may be provided on walls of the lower waveguide layer 20 and the upper waveguide layer 30. The current blocking layers 40 may have the same or similar thickness as the active waveguide layer 18. The current blocking layers 40 may have a thickness of about 0.7 to about 2.5 μm.

The current blocking layers 40 may concentrate currents towards the active waveguide layer 18. According to an example, the current blocking layers 40 may include a first current blocking layer 42 and a second current blocking layer 44. The first current blocking layer 42 may include p-type InP. The second current blocking layer 44 may be provided on the first current blocking layer 42. The second current blocking layer 44 may include n-type InP.

The clad layer 50 may be provided on the upper waveguide layer 30, and the current blocking layers 40. The clad layer 50 may have a lower energy bandgap lower than the lower waveguide layer 20 and the upper waveguide layer 30. The energy bandgap of the clad layer 50 may be the same or similar as the substrate 10. For example, the clad layer 50 may be about 1.35 eV. The clad layer 50 may include p-type InP.

An ohmic contact layer 52 may be provided on the clad layer 50. The ohmic contact layer 52 may reduce contact resistance between the clad layer 50 and an upper electrode 60. The ohmic contact layer 52 may include p-type InGaAs.

A protection layer 54 may be provided on the ohmic contact layer 52. The protection layer 54 may be provided outside the lower waveguide layer 20 and the upper waveguide layer 30. The protection layer 54 may expose the ohmic contact layer 52 on the lower waveguide layer 20 and the upper waveguide layer 30 such as FIG. 2A. For example, the protection layer 54 may include silicon nitride (SiN). Unlike this, the protection layer 54 may include silicon oxide (SiO2), and the inventive concept is not limited thereto.

The upper electrode 60 may be provided on the clad layer 50 of the lower waveguide layer 20 and the upper waveguide layer 30. The upper electrode 60 may be provided on a portion of the protection layer 54. The upper electrode 60 may be provided with a bias voltage. For example, the upper electrode 60 may include a metal including gold (Au), silver (Ag), aluminum (Al), copper (Cu), titanium (Ti), or platinum (Pt).

The lower electrode 70 may be provided on the lower surface of the substrate 10. The lower electrode 70 may be grounded. For example, the lower electrode 70 may include a metal including gold (Au), silver (Ag), aluminum (Al), copper (Cu), titanium (Ti), or platinum (Pt). When a bias voltage is supplied between the upper electrode 60 and the lower electrode 70, the super-luminescent diode 100 may acquire the gain of the laser light 102.

Finally, the super-luminescent diode 100 according to the inventive concept may have an asymmetric SCH layer and use the active waveguide layer 18 including the lower waveguide layer 20 and the upper waveguide layer 30, which are tapered in opposite directions in the tapered region 14, to operate at high power and high efficiency.

A manufacturing method of the super-luminescent diode 100 constituted in this way according to the inventive concept will be described as the following.

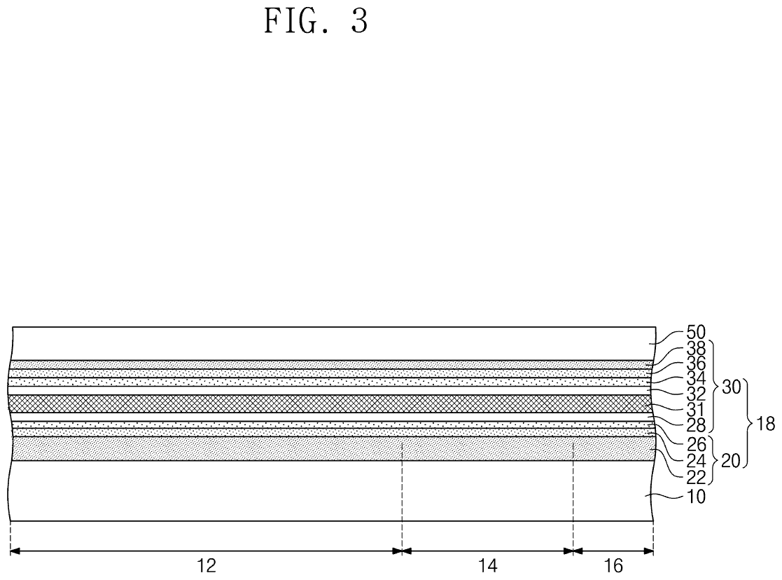

FIG. 3 shows an example of the lower waveguide layer 20, the upper waveguide layer 30, and the clad layer 50 of FIGS. 1 and 2A.

Referring to FIG. 3, the active waveguide layer 18 and the clad layer 50 are sequentially provided on the substrate 10. The active waveguide layer 18 may include the lower waveguide layer 20 having a plurality of asymmetric SCH layers, and the upper waveguide layer 30. The lower waveguide layer 20 may include the first lower SCH layer 22, the second lower SCH layer 24, and the third lower SCH layer 26. The upper waveguide layer 30 may include the fourth lower SCH layer 28, the core layer 31, the first upper SCH layer 36, the second upper SCH layer 34, the third upper SCH layer 36, and the fourth SCH layer 38. The first lower SCH layer 22, the second lower SCH layer 24, the third lower SCH layer 26 of the lower waveguide layer 20, and the fourth lower SCH layer 28 of the upper waveguide layer 30 may be provided in the structure of an asymmetric SCH. The core layer 31 of the upper waveguide layer 30 may have the structure in which the multi-quantum well layers 33 and the barrier layers 35 are alternately provided. The first upper SCH layer 32, the second upper SCH layer 34, the third upper SCH layer 36, and the four upper SCH layer 38 may be provided thinner than the first lower SCH layer 22, the second lower SCH layer 24, the third lower SCH layer 26, and the fourth lower SCH layer 28.

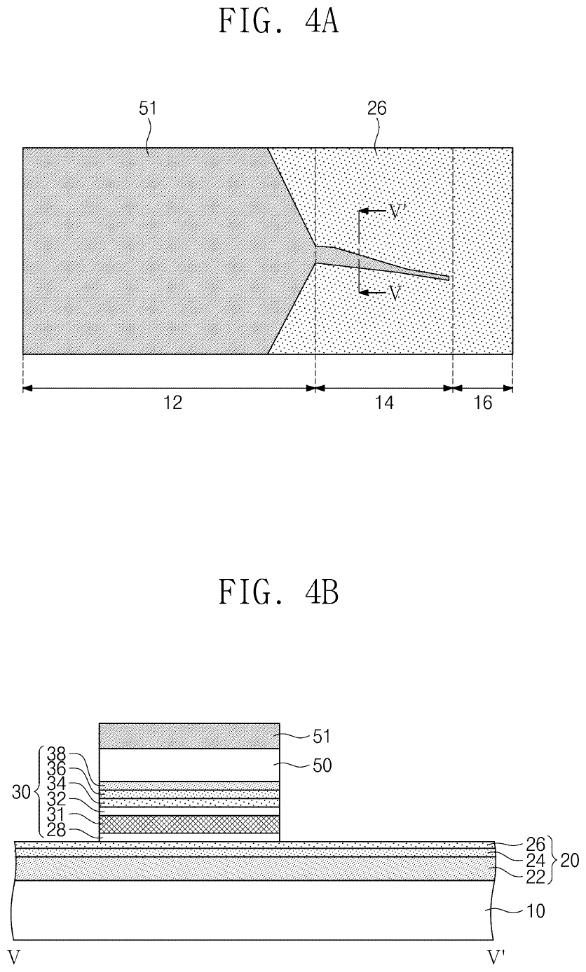

FIG. 4A shows an example first hard mask film 51 provided on the clad layer of FIG. 3. FIG. 4B shows a cross-sectional view taken along line V-V′ of FIG. 4A.

Referring to FIGS. 4A and 4B, the first hard mask film 51 is used as a mask layer to remove a portion of the upper waveguide layer 30 and the clad layer 50 and taper the upper waveguide layer 30. The first hard mask film 51 may include silicon nitride (SiN). The upper waveguide layer 30 and the clad layer 50 may be etched in a wet etching method or a dry etching method. When the upper waveguide layer 30 is tapered, a portion of the third lower SCH layer 26 may be exposed.

Then, the first hard mask film 51 is removed to expose the clad layer 50 in the gain region 12 and the tapered region 14. The first hard mask film 51 may be removed in a wet etching method.

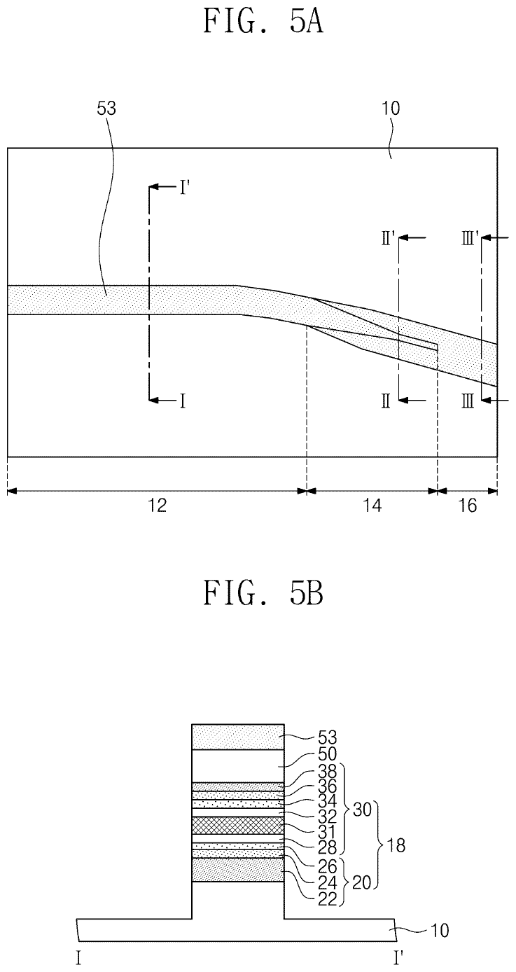

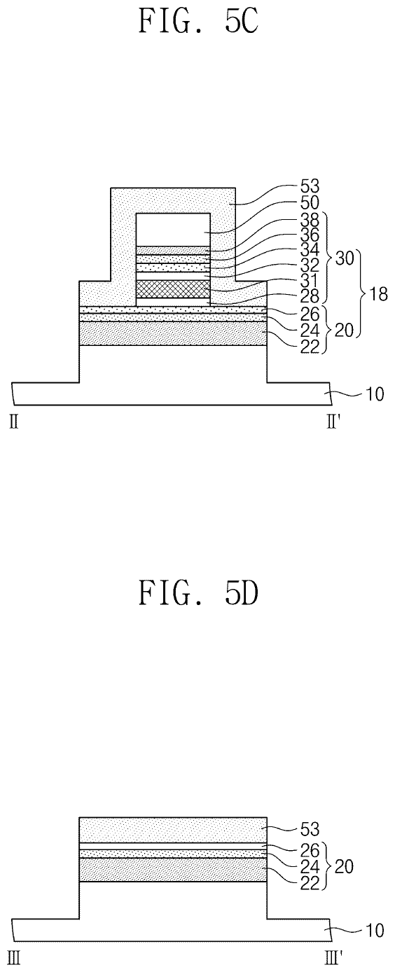

FIG. 5A shows an example second hard mask film 53 provided on the clad layer of FIG. 4B. FIGS. 5B, 5C, and 5D are cross sections of the gain region 12, the tapered region 14, and the window region 16 of FIG. 5A.

Referring to FIGS. 5A to 5D, the second hard mask film 53 is used as a mask layer to remove a portion of the lower waveguide layer 20, the upper waveguide layer 30, and the clad layer 50 to taper the lower waveguide layer 20 in the tapered region 14. The second hard mask film 53 may include silicon nitride (SiN). The upper waveguide layer 30 may be aligned with the lower waveguide layer 20 in the gain region 12. The lower waveguide layer 20 may be wider than the upper waveguide layer 30 in the window region 16.

Then, the second hard mask film 53 is removed. The second hard mask film 53 may be removed in a wet etching method.

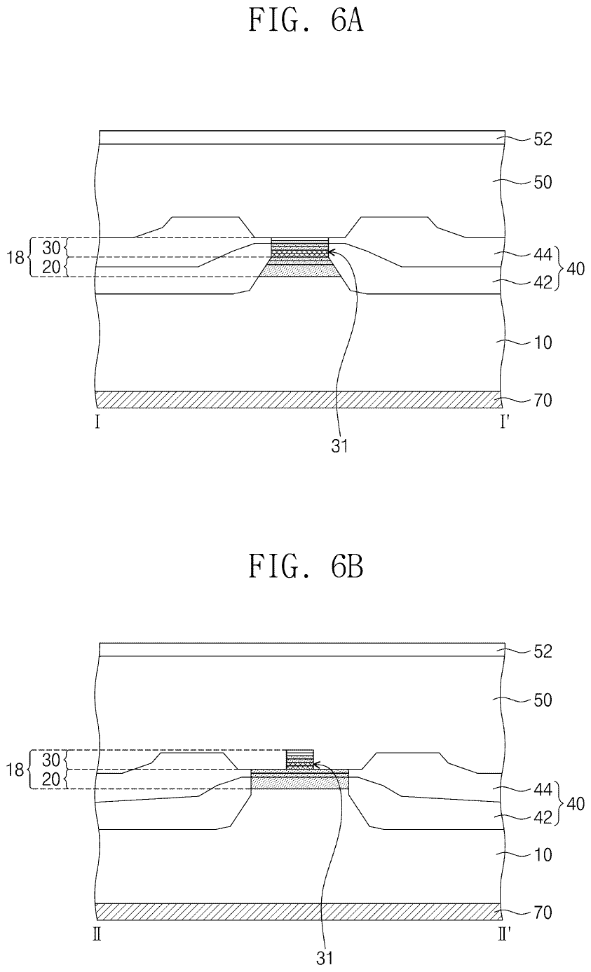

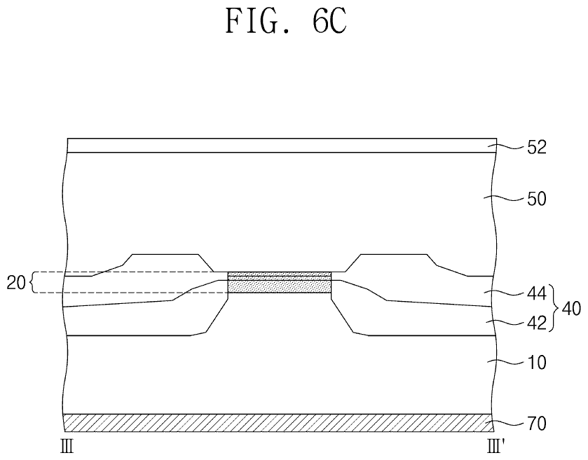

FIGS. 6A to 6C show examples of the current blocking layers 40, the clad layer 50, and the ohmic contact layer 52 of FIGS. 5B to 5D.

Referring to FIGS. 6A to 6C, the current blocking layers 40 are provided on walls of the lower waveguide layer 20 and the upper waveguide layer 30. The current blocking layers 40 may include a first current blocking layer 42, a second current blocking layer 44, and a third current blocking layer 46.

Then, the clad layer 50 is further provided on the lower waveguide layer 20, the upper waveguide layer 30, and the current blocking layers 40. The clad layer 50 may have a flat upper surface. The clad layer 50 may include p-type InP.

Then, the ohmic contact layer 52 is provided on the clad layer 50.

Referring to FIGS. 2A and 2D, the protection layer 54 is provided on the ohmic contact layer 52. For example, the protection layer 54 may include silicon nitride (SiN). The protection layer 54 may include silicon oxide (SiO2), and the inventive concept is not limited thereto.

Then, the protection layer 52 on the lower waveguide layer 20 and the upper waveguide layer 40 is removed to expose the ohmic contact layer 52 of the active waveguide layer 18. The protection layer 54 may be removed in a photolithography process and an etching process.

Then, the upper electrode 60 is provided on a portion of the ohmic contact layer 52 and the protection layer 54. The upper electrode 60 may be provided through a metal deposition process, a photolithography process and an etching process. The metal deposition process may include a sputtering method, a thermal deposition method, or a chemical vapor deposition method.

Furthermore, the lower electrode 70 is provided on the lower surface of the substrate 10. The lower electrode 70 may be provided by a metal deposition process.

FIG. 7 illustrates an external cavity laser 1000 according to an application example of the inventive concept.

Referring to FIG. 7, the external cavity laser 1000 according to the application example of the inventive concept may include an element substrate 500, a super-luminescent diode 100, a first coating layer 110, a second coating layer 120, a lens 200, a filter 300, and a mirror 400.

The element substrate 50 may support and fix the super-luminescent diode 100, the first coating layer 110, the second coating layer 120, the lens 200, the filter 300, and the mirror 400. For example, the element substrate 500 may include alumina (Al₂O₃), aluminum nitride (AlN), or a copper printed circuit board. Unlike this, the element substrate 500 may include Si, and the inventive concept is not limited thereto.

The super-luminescent diode 100 may be provided on one side of the element substrate 500. The super-luminescent diode 100 may acquire the gain of the laser light or generate the laser light 102.

The first coating layer 100 may be provided on one side of the super-luminescent diode 100. The first coating layer 110 may include a low reflective coating layer. The first coating layer 100 may reflect a portion of the laser light 102 to the super-luminescent diode 100 and output another portion of the laser light 102 to the outside. The laser light 102 may be output at high power or high efficiency through the first coating layer 100 on the one side of the super-luminescent diode 100.

The second coating layer 100 may be provided on the other side of the super-luminescent diode 100. The second coating layer 120 may include an anti-reflective coating layer or a transmissive layer. The second coating layer 120 may transmit the laser light 102 through the lens 200.

The lens 200 may be provided between the super-luminescent diode 100 and the filter 300. The lens 200 may enlarge and project the laser light 102 to the filter 300. The lens 200 may focus the laser light 102 to the super-luminescent diode 100.

The filter 300 may be provided between the lens 200 and the mirror 400. The filter 300 may determine the wavelength of the laser light 102. According to an example, the filter 300 may include a filter substrate 310, reflective layers 320, and transmissive layers 330. The filter substrate 310 may include transparent glass or transparent plastics. The reflective layers 320 may be provided on the filter substrate 310. The reflective layers 320 may transmit a portion of the laser light 102 and reflect another portion of the laser light 102. The transmissive layers 330 and the reflective layers 320 may be alternately laminated. The transmissive layers 330 may include silicon oxide. The reflective layers 320 of the filter 300 and the first coating layer 100 may resonate the laser light 102. The wavelength of the laser light 102 may correspond to the distance between the reflective layers 320.

The mirror 400 may receive the laser light 102 from the filter 300 and reflect again the laser light to the filter 300. The mirror 400 may include a total reflection mirror. The mirror 400 and the first coating layer 110 may resonate again the laser light 102.

Accordingly, the external cavity laser 100 according to the application example of the inventive concept may use the super-luminescent diode 100 to output the laser light 102 at high efficiency.

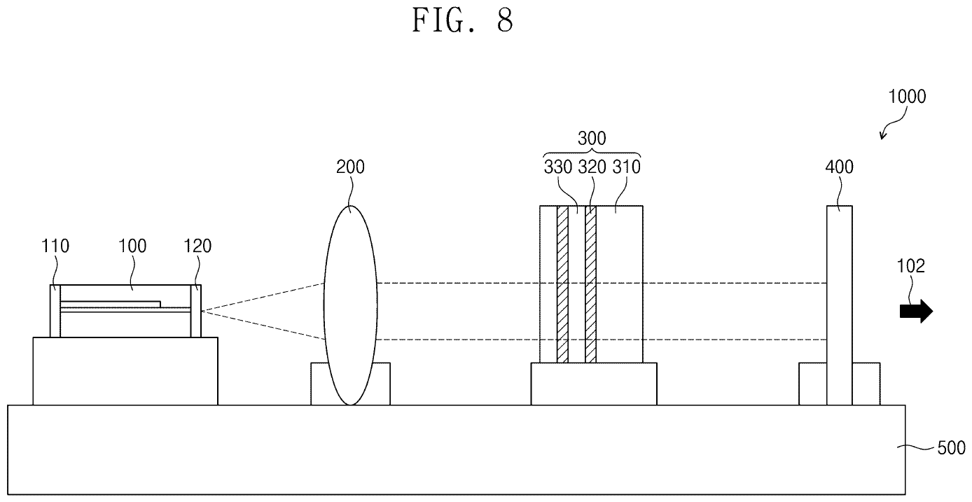

FIG. 8 illustrates the external cavity laser 1000 according to an application example of the inventive concept.

Referring to FIG. 8, the mirror 400 of the external cavity laser 1000 according to the application example of the inventive concept may output or transmit the laser light 102 to the outside. The mirror 400 may include a half mirror. The mirror 400 may reflect a portion of the laser light 102 to the filter 300 and transmit another portion of the laser light 102. The laser light 102 may be output at high power and high efficiency through the mirror 400.

The first coating layer 110 may be provided at one side of the super-luminescent diode 100 to reflect only a certain portion of the laser light 102. Namely, the first coating layer 110 may include a high reflective coating layer or a total reflective layer.

The element substrate 500, the super-luminescent diode 100, the second coating layer 120, the lens 200, and the filter 300 may be configured identically to those of FIG. 7.

The super-luminescent diode according to an embodiment of the inventive concept includes the asymmetric SCH layers in the tapered region, and may use lower and upper waveguide layers tapered in opposite directions to operate at high power and high efficiency.

As described above, the embodiments are disclosed in the drawings and the specification. Herein, specific terms have been used, but are just used for the purpose of describing the inventive concept and are not used for defining the meaning or limiting the scope of the inventive concept, which is disclosed in the appended claims. Thus, it would be appreciated by those skilled in the art that various modifications and other equivalent embodiments can be made. Therefore, the true technical scope of the inventive concept shall be defined by the technical spirit of the appended claims.

What is claimed is:

1. A super-luminescent diode comprising:
a substrate including a gain region, a window region spaced apart from the gain region, and a tapered region between the window region and the gain region;
an active waveguide layer including a lower waveguide layer provided on the substrate and extending from the gain region to the window region, and an upper waveguide layer provided on the lower waveguide layer and extending from the gain region to the tapered region; and
a clad layer provided on the lower waveguide layer and the upper waveguide layer of the active waveguide layer,
wherein each of the lower waveguide layer and the upper waveguide layer comprises asymmetric separate confinement heterostructure (SCH) layers.

2. The super-luminescent diode of claim 1,
wherein the lower waveguide layer and the upper waveguide layer are tapered in opposite directions in the tapered region.

3. The super-luminescent diode of claim 1,
wherein the lower waveguide layer comprises:
a first lower SCH layer having an energy bandgap higher than that of the substrate;
a second lower SCH layer provided on the first lower SCH layer, the second lower SCH layer being thinner than that of the first lower SCH layer and having an energy bandgap higher than that of the first lower SCH layer; and
a third lower SCH layer provided on the second lower SCH layer and having an energy bandgap higher than that of the second lower SCH layer.

4. The super-luminescent diode of claim 3,
wherein the upper waveguide layer comprises:
a fourth lower SCH layer provided on the third lower SCH layer and having an energy bandgap higher than that of the third lower SCH layer; and
a core layer provided on the fourth lower SCH layer and including quantum well structures and barrier layers between the quantum well structures.

5. The super-luminescent diode of claim 4,
wherein the upper waveguide layer is provided on the core layer and further comprises a first upper SCH layer having same energy bandgap as that of the fourth lower SCH layer.

6. The super-luminescent diode of claim 5,
wherein the upper waveguide layer is provided on the first upper SCH layer and further comprises a second upper SCH layer having same energy bandgap as that of the third lower SCH layer.

7. The super-luminescent diode of claim 6,
wherein the upper waveguide layer is provided on the second upper SCH layer and further comprises a third upper SCH layer having same energy bandgap as that of the second lower SCH layer.

8. The super-luminescent diode of claim 7,
wherein the upper waveguide layer is provided on the third upper SCH layer and further comprises a fourth upper SCH layer having same energy bandgap as that of the first lower SCH layer.

9. The super-luminescent diode of claim 8,
wherein each of the first lower SCH layer, the second lower SCH layer, the third lower SCH layer, the fourth lower SCH layer, the core layer, the first upper SCH layer, the second upper SCH layer, the third upper SCH layer, and the fourth upper SCH layer comprises InGaAsP.

10. The super-luminescent diode of claim 1, further comprising:
an ohmic contact layer on the clad layer;
an upper electrode on the ohmic contact layer; and
a lower electrode under the substrate.

11. An external cavity laser comprising:
an element substrate;
a super-luminescent diode provided at one side of the element substrate;
a mirror provided at another side of the element substrate; and
an optical filter provided between the mirror and the super-luminescent diode,
wherein the super-luminescent diode comprises:
a substrate including a gain region, a window region spaced apart from the gain region, and a tapered region between the window region and the gain region;
an active waveguide layer including a lower waveguide layer provided on the substrate and extending from the gain region to the window region, and an upper waveguide layer provided on the lower waveguide layer and extending from the gain region to the tapered region; and
a clad layer provided on the lower waveguide layer and the upper waveguide layer of the active waveguide layer,
wherein each of the lower waveguide layer and the upper waveguide layer comprises asymmetric separate confinement heterostructure (SCH) layers.

12. The external cavity laser of claim 11, further comprising:
a first coating layer provided at one side of the super-luminescent diode; and
a second coating layer provided at another side of the super-luminescent diode.

13. The external cavity laser of claim 12, wherein
the first coating layer comprises a half-transmissive coating layer or a total-reflective coating layer, and
the second coating layer comprises an anti-reflective layer.

14. The external cavity laser of claim 11,
wherein the filter comprises:
a filter substrate;
half-transmissive layers on the filter substrate; and
transmissive layers between the half-transmissive layers.

15. The external cavity laser of claim 11,
further comprising a lens provided between the filter and the super-luminescent diode.

16. A super-luminescent diode manufacturing method comprising:
providing a lower waveguide layer and an upper waveguide layer on a substrate including a gain region, a window region spaced apart from the gain region, and a tapered region between the gain region and the window region;
removing a portion of the upper waveguide layer in the tapered region and the window region to taper the upper waveguide layer in the tapered region in one direction; and
removing a portion of the upper waveguide layer in the gain region and a portion of the lower waveguide layer and the upper waveguide layer in the gain region, the tapered region, and the window region to taper the lower waveguide layer in a direction opposite to the tapering direction of the upper waveguide layer,
wherein each of the upper waveguide layer and the lower waveguide layer comprises asymmetric SCH layers.

17. The super-luminescent diode manufacturing method of claim 16, further comprising
providing a current blocking layer on walls of the lower waveguide layer and the upper waveguide layer.

18. The super-luminescent diode manufacturing method of claim 17, further comprising:
providing a clad layer on the current blocking layer, the upper waveguide layer, and the lower waveguide layer;
providing an ohmic contact layer on the clad layer;
providing an upper electrode on the ohmic contact layer; and
providing a lower electrode on a lower surface of the substrate.

19. The super-luminescent diode manufacturing method of claim 16,
wherein the lower waveguide layer comprises:
a first lower SCH layer having an energy bandgap higher than that of the substrate;
a second lower SCH layer provided on the first lower SCH layer, being thinner than the first lower SCH layer, and having an energy bandgap higher than that of the first lower SCH layer; and
a third lower SCH layer provided on the second lower SCH layer and having an energy bandgap higher than that of the second lower SCH layer.

20. The super-luminescent diode manufacturing method of claim 19,
wherein the upper waveguide layer comprises:
a fourth lower SCH layer provided on the third lower SCH layer and having an energy bandgap higher than that of the third lower SCH layer;
a core layer provided on the fourth lower SCH layer and including quantum well structures and barrier layers between the quantum well structures;
a first upper waveguide layer provided on the core layer and having same energy bandgap as that of the fourth lower SCH layer;
a second upper SCH layer provided on the first upper SCH layer and having same energy bandgap as that of the third lower SCH layer;
a third lower SCH layer provided on the second upper SCH layer and having same energy bandgap as that of the second lower SCH layer; and
a fourth upper SCH layer provided on the third upper SCH layer and having same energy bandgap as that of the first lower SCH layer.
